(19) United States
(12) Patent Application Publication
(10) Pub. No.: US 2009/0228751 A1
(43) Pub. Date: Sep. 10, 2009

(54) METHOD FOR PERFORMING LOGIC BUILT-IN-SELF-TEST CYCLES ON A SEMICONDUCTOR CHIP AND A CORRESPONDING SEMICONDUCTOR CHIP WITH A TEST ENGINE

(76) Inventors: Tilman Gloekler, Gaertringen (DE); Christoph Jaeschke, Tuebingen (DE); Thuyen Le, Taufkirchen (DE); Martin Padeffke, Hildrizhausen (DE)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 12/125,476

(22) Filed: May 22, 2008

(30) Foreign Application Priority Data
May 22, 2007 (DE) 07108640.9

(51) Int. Cl. G01R 31/3177; G06F 11/25

(52) U.S. Cl. 714/728; 714/733; 714/731; 714/E11.155

(57) ABSTRACT

A method, structure and design system for performing logic built-in-self-test (LBIST) cycles on a semiconductor chip with a plurality of logic circuits and a plurality of storage elements connected serially to a number of LBIST stumps (pattern segments) between a pseudo-random-pattern generator (30) and a multiple-input-signature register. The semiconductor chip is subdivided into partitions, such that LBIST cycles may be run separately or in parallel for one or more partitions. The LBIST cycles may also be run separately or in parallel inter-connections between the partitions. The partitions to be tested are controlled by at least one corresponding clock signal, and the inter-connections to be tested are controlled by at least one corresponding clock signal.

The field of the invention relates to a method for performing logic built-in-self-test cycles on a semiconductor chip, and more particularly to a corresponding semiconductor chip with a test engine and design methodology for same.

An integrated circuit on a semiconductor chip comprises a plurality of storage elements and logic circuits. For example, the storage elements are realized as flip-flop elements. The logic circuits may be realized as gate logic circuits. During the manufacturing process of the semiconductor chip the integrated circuit has to be tested in order to detect defects.

A well known example of a method for testing high speed integrated circuits is a logic built-in-self-test (LBIST) element. LBIST allows testing the logic of the semiconductor chip at the rated clock speed of the system. LBIST uses pseudo-random pattern generators (PRPG) to initialize LBIST-able scan chains, referred to as LBIST stumps. The LBIST stump is formed by a series of a plurality of scan-able storage elements. Like other storage elements, the scan-able storage element comprises a data input and a data output. Additionally, the scan-able storage element comprises a scan input and a scan output. The scan output of one scan-able storage element is connected to the scan input of the next scan-able storage element. In this way the scan-able storage elements form the LBIST stump.

The PRPG generates pseudo-random patterns, which are driven into the LBIST stumps. The PRPG initializes the LBIST stumps through their scan inputs at the maximum scan frequency. Subsequently, the LBIST switches to the system clock frequency of the product and exercises the functional logic between the LBIST stumps and updates the storage elements of the LBIST stumps. After the functional logic updates, the LBIST stumps scan out the updated values into multiple-input-signature registers (MISR), while simultaneously scanning in new values from the PRPG. The results from the LBIST stump are serially compressed into the MISR. The registers of the MISR capture a signature that is used to identify faults after running enough LBIST iterations.

For very complex and high speed integrated circuits the conventional LBIST techniques to test the complete semiconductor chip becomes more difficult. Switching activity associated with LBIST results in excessive power consumption. Power consumption may be reduced by subdividing the semiconductor chip into partitions, so that only one partition of the semiconductor chip is tested at a time. However, this results in two additional problems. First, the inter-connections between LBIST-able partitions on the semiconductor chip cannot be tested. Second, the contributions from non-LBIST-able partitions may result in non-reproducible LBIST signatures for good semiconductor chips.

Known solutions for testing the inter-connections between the partitions, include manually designed tests, which exercise these connections. For example, a special program is run on a microprocessor. These solutions are very expensive in terms of manual effort and test time. Further, these solutions result in very limited coverage for manufacturing faults.

A known solution to obtain reproducible signatures on one partition is to scan the other partitions to a known state and then hold them in that state, while running LBIST on only one partition. However, the test of the inter-connections between the partitions is impractical with this setup.

### SUMMARY

The foregoing discussed drawbacks and deficiencies of the prior art are overcome or alleviated, in an exemplary embodiment, by a method as set forth in the independent claims. Further advantageous embodiments are described in the dependent claims and are taught in the description below.

The core idea of the invention is to suppress the signals from the non-scan-able storage elements and from the inter-connection between the partitions. This is realized by controlling the clock signals in the functional path. The control logic may be realized by a relatively small number of gates. Thus, the cost in terms of the additional logic is negligible. Only the additional logic for clock gating is required.

The storage elements are grouped on the semiconductor chip and each group is provided with an individual clock signal.

The invention provides two different modes for running a logic built-in-self-test (LBIST). In the first mode the LBIST is running on one or several complete partitions at a time. In the second mode the LBIST is running on the inter-connections between the partitions. Thereby the LBIST is started synchronously on the boundaries of all partitions to be tested. If the power budget allows it, the modes can be combined in a flexible way. For example, the LBIST runs only a subset of the partitions and on some or all inter-connections at a time.

The signatures are supposed to be reproducible in both modes, since the contributions from the non-LBIST-able logic circuits are suppressed. This is achieved by disabling the clock signal for storage elements connected to the non-LBIST-able logic circuits.

In particular, one or more special LBIST stumps are implemented, which contain only input and/or output registers of a partition. The modes are selectable in conjunction with a proper clock network.

A preferred embodiment allows high fault coverage with a fully automatic LBIST operation. The LBIST operation may be performed for regular logic partitions as well as for the interconnection logic or glue logic. Reproducible signatures are enforced by this test architecture of the semiconductor chip. Manual setups are not necessary before running the LBIST. The connections between the partitions can be tested without defining manual tests.

The overall power consumption on the semiconductor chip can be controlled and limited by running LBIST only on a subset of the partitions in parallel.

### BRIEF DESCRIPTION OF THE DRAWINGS

Referring to the exemplary drawings wherein like elements are numbered alike in the several Figures:

FIG. 1 illustrates a flow chart diagram of a method for performing a manufacturing test according to a preferred embodiment;

FIG. 2 illustrates a flow chart diagram of a method for performing a manufacturing test according to a generalized embodiment of the present invention;

FIG. 3 illustrates a schematic diagram of an integrated circuit with a number of LBIST stumps arranged between a pseudo-random pattern generator (PRPG) and a multiple-input-signature register (MISR) according to the preferred embodiment;

FIG. 4 illustrates a schematic diagram of an integrated circuit on a semiconductor chip according to the preferred embodiment;

FIG. 5 illustrates a flow chart diagram of a method for designing the integrated circuit on a semiconductor chip; and

FIG. 6 illustrates a schematic diagram of an initial chip design for an integrated circuit according to the preferred embodiment.

### DETAILED DESCRIPTION

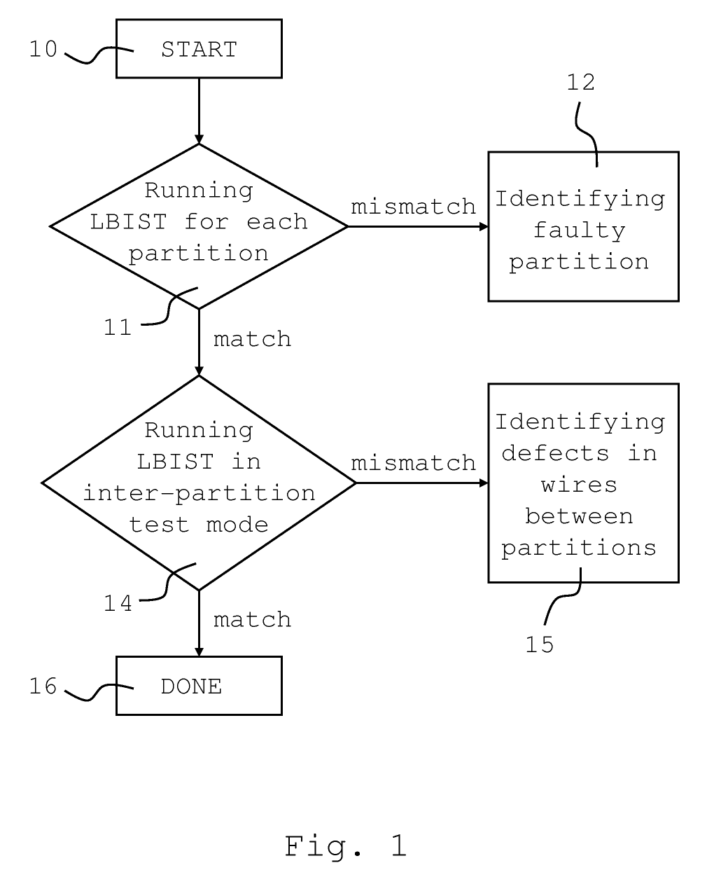

FIG. 1 illustrates a flow chart diagram of performing a manufacturing test for an integrated circuit on a semiconductor chip according to a special embodiment of the present invention. The integrated circuit on the semiconductor chip is subdivided into partitions.

In a first step 10 the manufacturing test for the integrated circuit is started. In a next step 11 a run of the manufacturing test in a first mode is performed. In said first test mode a logic built-in-self-test (LBIST) is running separately or in parallel for each partition, without testing the inter-partition interfaces. If a resulting signature mismatches with a reference signature, then a faulty partition can be clearly identified. If the signature of all the partitions matches with corresponding reference signatures, then a step 14 is performed. In the step 14 a LBIST for the inter-connections between the LBIST-able partitions is running. If the resulting signature of an inter-connection does not match with a corresponding reference signature, then a defect in the wires between the partitions may be identified. If the resulting signatures of all inter-connections match with corresponding reference signatures, then a last step 16 is performed. The last step 16 finishes the manufacturing test.

The manufacturing test according to the preferred embodiment includes several LBIST steps. The order of the steps 11 and 14 does not matter. If the power budget permits, steps 11 and 14 may run in parallel on at least some partitions and interconnections.

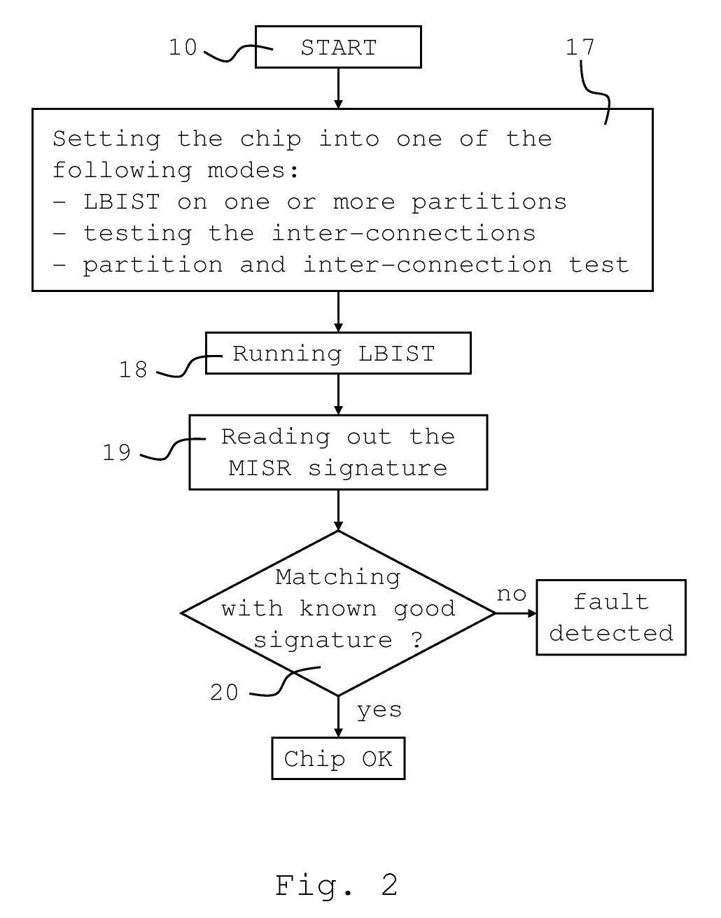

FIG. 2 illustrates a flow chart diagram of the method for performing a manufacturing test according to a generalized embodiment. In the step 10 the manufacturing test is started. In the next step 17 the integrated circuit is set into one of three possible test modes. The first test mode is an LBIST on one or more partitions. The second test mode is an LBIST for the inter-connections between the partitions. The third test mode includes parallel LBIST manufacturing tests with the LBIST of the partitions and the LBIST of the inter-connections. In a next step 18 the LBIST is running. In a further step 19 a signature is read out from a multiple input signature register (MISR). In a last step 20 the signature is compared with a reference signature. If the signature matches with the reference signature, then the integrated circuit is defect-free. If the signature does not match with the reference signature, then a fault in the integrated circuit on the semiconductor chip is detected.

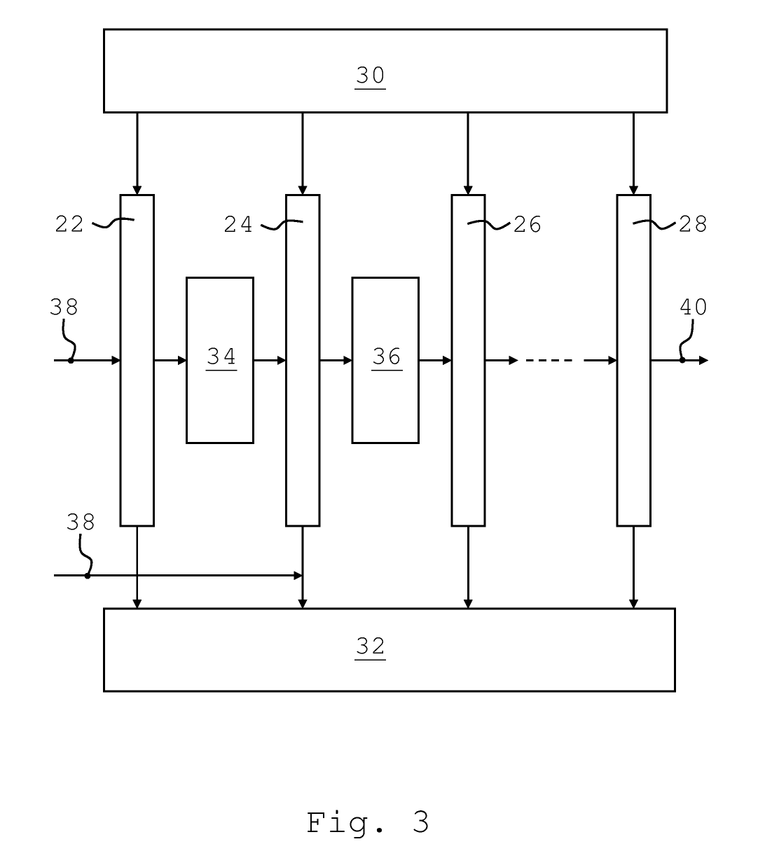

FIG. 3 illustrates a schematic diagram of an integrated circuit with a number of LBIST stumps arranged between a pseudo-random pattern generator (PRPG) 30 and a multiple-input-signature register (MISR) 32 according to the preferred embodiment. The integrated circuit comprises a plurality of LBIST stumps. A part of LBIST stumps 22, 24, 26 and 28 is shown in FIG. 3. Each LBIST stump 22, 24, 26 and 28 includes a plurality of storage elements serially connected together. The storage elements are serially connected by scan input and scan output terminals. The storage element may be realized as a flip-flop element. Each LBIST stump 22, 24, 26 and 28 forms a shift register. LBIST stumps 22, 24, 26 and 28 are usually also referred to as scan chains.

LBIST stumps 22, 24, 26 and 28 are arranged between a pseudo-random pattern generator (PRPG) 30 and a multiple input signature register (MISR) 32. The input of each LBIST stump 22, 24, 26 and 28 is connected to one output of the PRPG 30, respectively. The outputs of the LBIST stumps 22, 24, 26 and 28 are connected to the MISR 32. The PRPG 30 and the MISR 32 are also arranged on the integrated circuit. The PRPG 30 generates pseudo-random patterns that are propagated into LBIST stumps 22, 24, 26 and 28. The results from the LBIST stump are serially compressed into the MISR 32. The registers of the MISR 32 capture a signature that is used to identify faults after running enough LBIST iterations. Between LBIST stumps 22, 24, 26 and 28 combinational logic blocks 34 and 36 are arranged.

In this embodiment the first LBIST stump 22 consists of input registers and the last LBIST stump 28 consists of output registers realized by one or more storage elements.

Alternatively, other constellations of LBIST stumps 22, 24, 26 and 28 are possible. For example, one single LBIST stump contains exclusively the input and output registers. According to another example, multiple LBIST stumps contain exclusively input and output registers.

In step 11 of FIG. 1, in which the LBIST is running for one or more partitions only, all LBIST stumps 22, 24, 26 and 28 are loaded with data from PRPG 30 in a scan phase. Afterwards, in functional update cycles, only LBIST stumps 24, 26 and 28 are updated, but not LBIST stump 22 with the input registers. This procedure allows performing an LBIST in the partition itself without capturing inputs from other partitions. In the scan-out phase and in the reload phase of the PRPG 30 all LBIST stumps 22, 24, 26 and 28 are scanned again. This allows controlling the values in the input registers of LBIST stump 22 as well, which results in optimum controllability.

In step 14 of FIG. 1, in which the inter-partition connection is tested, the data from the PRPG 30 is loaded only into the first LBIST stump 22 and into the last LBIST stump 28 in the scan phase for all partitions in a chip. Later, only the data from the first LBIST stump 22 and the last LBIST stump 28 are shifted into the MISR 32 again for all partitions in the chip. In a subsequent functional cycle or in several subsequent functional cycles only the first LBIST stump 22 is updated. This allows testing the interconnections between the partitions. This allows further a significant reduction of the power consumption of the semiconductor chip during test.

The contributions from non-LBIST-able partitions have to be suppressed in order to avoid irreproducible signatures. Those special input registers, which are connected to non-LBIST-able partitions and receive signals from those non-LBIST-able partitions, have to be scanned to known values and hold their value in any functional cycle for both LBIST modes. These requirements on when the register is supposed to update and when the register is supposed to hold have to be met by a proper clock gating implementation. In order to achieve this functionality, the input registers according to the present invention are subdivided into two kinds of input registers. The input registers of the first kind are driven by a logic circuit, which is tested by an LBIST cycle. The input registers of the second kind are driven by a logic circuit, which is not LBIST-able.

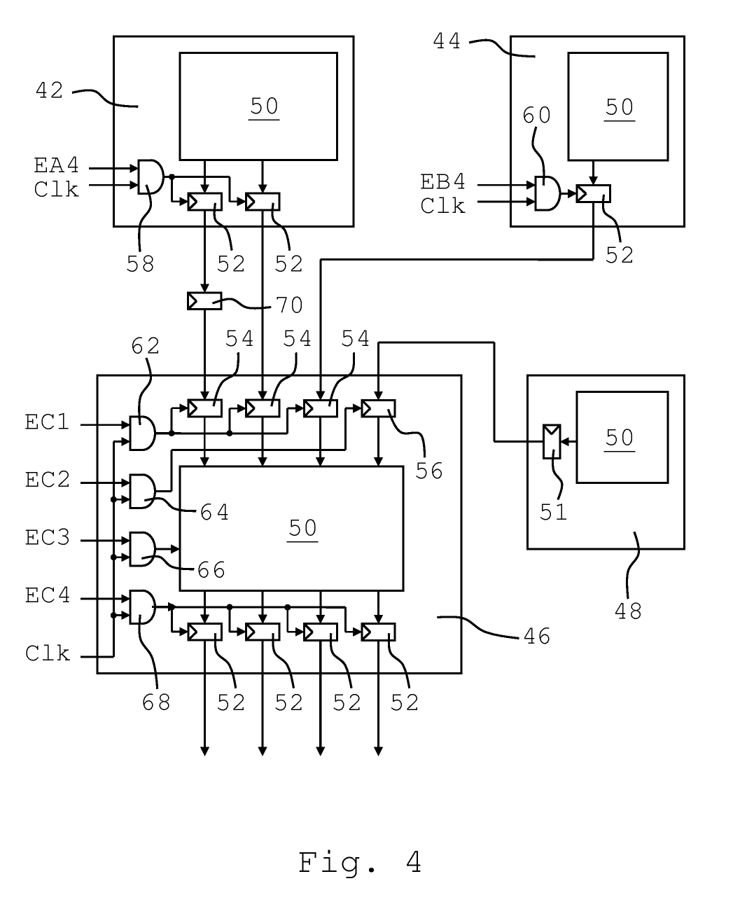

FIG. 4 illustrates such a part of an integrated circuit on a semiconductor chip according to a preferred embodiment. The integrated circuit is subdivided, comprising a first partition 42, a second partition 44, a third partition 46 and a fourth partition 48. Each of which includes a logic partition 50. Further, partitions 42, 44 and 46 include one or more output registers 52. Partition 48 includes output register 51, which includes one or more storage elements. Third partition 46 comprises three LBIST-able input registers 54 and one non-LBIST-able input register 56. LBIST-able input register 54 as well as non-LBIST-able input registers 56 include one or more scan-able storage elements. The scan-able storage element contains a separate scan input and scan output, which are not shown in FIG. 4. In this example, input register 56 of partition 46 is non-LBIST-able, because the output register 51 of partition 48 is non-LBIST-able. This means, that the path between output register 51 of partition 48 and input register 56 of partition 46 is not testable by LBIST. This also means that the logic value of register 51 of partition 48 can not be controlled during LBIST operation and has to be suppressed while running LBIST in partition 46.

First partition 42 contains AND gate 58 with two input terminals, one connected to a clock signal Clk and the other to a clock enable signal EA4. The output terminal of the AND gate 58 is connected to the clock input terminals of the output registers 52 of the first partition 42.

The second partition 44 comprises an AND gate 60 with two input terminals. The one input terminal of the AND gate 60 is connected to the clock signal Clk. The other input terminal of the AND gate 60 is connected to a clock enable signal EB4. The output terminal of the AND gate 60 is connected to the clock input terminals of the output registers 52 of the second partition 44.

The third partition 46 comprises a first AND gate 62, a second AND gate 64, a third AND gate 66 and a fourth AND gate 68. Each of AND gates 62, 64, 66 and 68 has two input terminals. One input terminal of each AND gate 62, 64, 66 and 68 is connected to clock signal Clk. The other input terminal of the first AND gate 62 is connected to a first clock enable signal EC1. The other input terminal of the second AND gate 64 is connected to a second clock enable signal EC2. The other input terminal of the third AND gate 66 is connected to a third clock enable signal EC3. The other input terminal of the fourth AND gate 68 is connected to a fourth clock enable signal EC4.

Between the first partition 42 and the third partition 46 there is a register 70. In this example, register 70 is provided to retime the signals, so that these signals may be synchronously sampled by the partition 46. In general, register 70 is a relatively small circuit between partitions 42, 44, 46, 48 and may be also provided for other applications. The LBIST for the inter-connections in the step 14 of FIG. 1 includes also the test of the register 70 and any other glue logic that might be present in other embodiments.

The output terminal of the first AND gate 62 is connected to the clock input terminals of the scan-able input registers 54 of the third partition 46. The output terminal of the second AND gate 64 is connected to the clock input terminal of the input register 56 of the third partition 46. The output terminal of the third AND gate 66 is connected to the logic partition 50 of the third partition 46. The output terminal of the fourth AND gate 68 is connected to the clock input terminals of the output registers 52 of the third partition 46.

The clock enable signals EC1, EC2, EC3 and EC4 may control, when the registers 52, 54 and 56 and the logic partition 50 of the third partition are provided with the clock signal Clk. In the same way the clock enable signal EA4 controls the clock signal Clk to the output registers 52 of the first partition 42, and the clock enable signal EB4 controls the clock signal Clk to the output register 52 of the second partition 44.

By the clock enable signals EC1 and EC2 the contributions from other partitions and/or from non-LBIST-able logic circuit may be suppressed as a function of the test mode. Specifically in the embodiment of FIG. 4, the logic contribution from the non-LBIST-able output register 51 of partition 48 needs to be suppressed in all functional updates in order to enforce reproducible MISR signatures. The clock enable signal EC4 allows the enabling of the update of the output registers 52. The clock enable signal EC3 allows the enabling of the update of the remaining internal registers in the logic partition 50.

The following table shows the logical states of the clock enable signals EC1, EC2, EC3 and EC4 for the third partition 46 of the integrated circuit. The clock enable signals EA4 and EB4 have the same effect as the clock enable signal EC4. The table shows the logical states of the clock enable signals EC1, EC2, EC3 and EC4 for the different test modes as well as the functional modes “partition is running” and “partition in hold mode”.

| LBIST mode | internal mode | EC1 | EC2 | EC3 | EC4 |
|---|---|---|---|---|---|
| LBIST in only one | scan phase | 1 | 1 | 1 | 1 |
| partition | functional update | 0 | 0 | 1 | 1 |
| inter-partition | scan phase | 1 | 1 | 0 | 1 |
| connection test | functional update | 1 | 0 | 0 | 0 |
| both modes in | scan phase | 1 | 1 | 1 | 1 |
| parallel | functional update | 1 | 0 | 1 | 1 |
| partition is running | functional mode | 1 | 1 | 1 | 1 |
| partition in hold mode | functional mode | 0 | 0 | 0 | 0 |

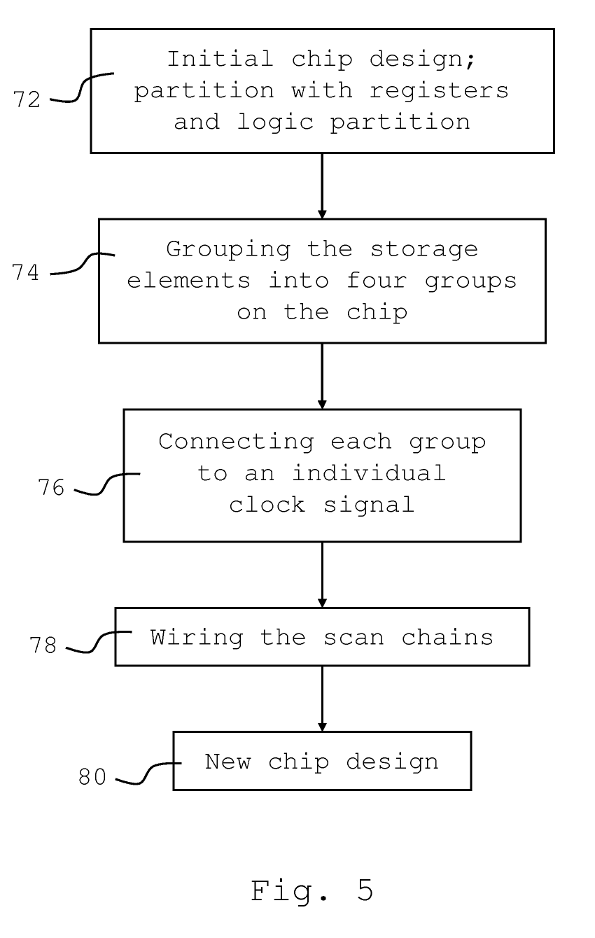

In FIG. 5 a flow chart diagram of a method for designing the integrated circuit on the semiconductor chip according to the present invention is shown. In a first step 72 a conventional chip design is prepared. Said chip design is subdivided into partitions. Each partition comprises at least a register and a logic circuit. The register includes one or more storage elements. In a next step 74 the storage elements are grouped into four groups on the chip design. Each group is connected to an individual clock signal in a further step 76. In a next step 78 the scan chain are wired by serially connecting the scan-able storage elements via the scan inputs and scan outputs. In a last step 80 a new chip design according to the preferred embodiment is ready. Specifically, in a preferred embodiment, the said groups are input registers with input from LBIST-able output registers, input registers with input from non-LBIST-able output registers, output registers and remaining internal registers. Said remaining internal registers are neither input nor output registers of a partition.

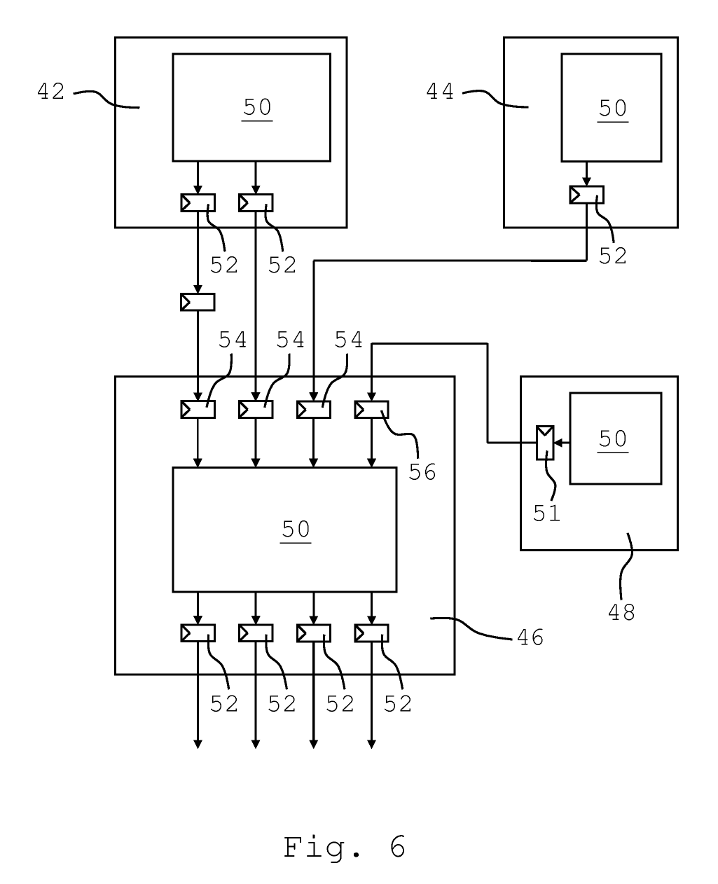

FIG. 6 illustrates a schematic diagram of the initial chip design according to the preferred embodiment. The design of the integrated circuit corresponds to the initial chip design in step 72 of FIG. 5. The integrated circuit is subdivided into a first partition 42, a second partition 44, a third partition 46 and a fourth partition 48, each of which includes a logic partition 50. Further, partitions 42, 44 and 46 include one or more output registers 52, which contain one or more storage elements. The partition 48 includes a register 51. The third partition 46 comprises three LBIST-able input registers 54 and one non-LBIST-able input register 56. The LBIST-able input register 54 includes one or more scan-able storage elements. The scan-able storage element comprises additionally a separate scan input and scan output, which are not shown in FIG. 4. The non-LBIST-able input register 56 includes one or more scan-able storage elements.

The preferred embodiments can also be embedded in a computer program product, which comprises all the features enabling the implementation of the methods described herein. Further, when loaded in computer system, said computer program product is able to carry out these methods.

Although illustrative embodiments of the present invention have been described herein with reference to the accompanying drawings, it is to be understood that the present invention is not limited to those precise embodiments, and that various other changes and modifications may be performed therein by one skilled in the art without departing from the scope or spirit of the invention. All such changes and modifications are intended to be included within the scope of the invention as defined by the appended claims.

What is claimed is:

1. A method for performing logic built-in-self-test (LBIST) cycles on a semiconductor chip with a plurality of logic circuits and a plurality of storage elements connected serially to a number of LBIST stumps between a pseudo-random-pattern generator and a multiple-input-signature register, comprising:
subdividing the semiconductor chip into a plurality of partitions;
Running the logic built-in-self-test cycles separately or in parallel for one or more the plurality of partitions;
Running the logic built-in-self-test cycles separately or in parallel for inter-connections between the plurality of partitions;
controlling the plurality of partitions to be tested by at least one corresponding clock signal; and
controlling the inter-connections to be tested by at least one corresponding clock signal.

2. The method according to claim 1, wherein a first predetermined LBIST stump includes exclusively input registers receiving input from LBIST-able registers having at least one storage element.

3. The method according to claim 2, wherein a second predetermined LBIST stump includes exclusively input registers receiving input from non-LBIST-able registers having at least one storage element.

4. The method according to claim 3, wherein a predetermined LBIST stump includes exclusively output registers having at least one storage element.

5. The method according to claim 4, wherein a predetermined LBIST stump includes exclusively input and output registers.

6. The method according to claim 5, wherein the plurality of partitions or the inter-connections between the plurality partitions are controlled by corresponding clock enable signals.

7. The method according to claim 6, wherein the LBIST cycles are running in parallel on the plurality of partitions and the inter-connections.

8. The method according to claim 8, wherein the LBIST cycles are running simultaneously on a subset of the partitions and the inter-connections.

9. An integrated circuit, comprising:
a plurality of logic elements, each partitioned into separately testable functional units;
a plurality of LBIST stumps (scan chains) each comprising a plurality of storage elements configured as individual shift registers, the plurality of LBIST stumps coupled to a corresponding one of the plurality of logic;
a pseudo-random-pattern generator (PRPG) configured to output a plurality of test patterns to each of the plurality of LBIST stumps; and
a multiple-input-signature register (MISR) coupled to the plurality of LBIST stumps, wherein a scan chain output from each of the plurality of LBIST stumps is input to a corresponding input of the MISR;
an interconnect structure providing connectivity between the plurality of logic elements, the interconnect structure being separately testable by LBIST; and
a controller logic element adapted to control individual clock signals driving the plurality of logic elements partitioned into functional units and the inter-connections.

10. The integrated circuit according to claim 9, further comprising a plurality of input registers for each of the partitioned functional logic units, the plurality of input registers for each corresponding functional logic unit being serially connected together within one single LBIST stump.

11. The integrated circuit according to claim 10, further comprising a plurality of output registers for each of the partitioned functional logic units, the plurality of output registers for each corresponding functional logic unit being serially connected together within one single LBIST stump.

12. The integrated circuit according to claim to 11, further comprising the plurality of input registers and the plurality of output registers of each functional logic unit being serially connected together within one single LBIST stump.

13. The integrated circuit according to claim 12, wherein the logic for controlling the individual clock signals comprises a dedicated logic gate for each input and output register.

14. The integrated circuit according to claim 13, wherein the logic for controlling the individual clock signals comprises a plurality of logical AND gates.

15. The integrated circuit according to claim 14, wherein the logical AND gates are controlled by individual corresponding clock enable signals.

16. The integrated circuit according to claim 15, further comprising non-LBIST-able logic in one or more partitions.

17. A method for designing an integrated circuit on a semiconductor chip, comprising
preparing an initial semiconductor chip design with storage elements and logic circuits;
grouping the storage elements into a number groups on the semiconductor chip;
connecting each group to an individual clock signal, and
wiring the storage elements to scan chains.

18. The method according to claim 17, wherein the method is realized in hardware, software or a combination of hardware and software.

19. A computer program product stored on a computer usable medium, comprising computer readable program means for causing a computer to perform a method comprising:
subdividing the semiconductor chip into a plurality of partitions;
Running the logic built-in-self-test cycles separately or in parallel for one or more the plurality of partitions;
Running the logic built-in-self-test cycles separately or in parallel for inter-connections between the plurality of partitions;
controlling the plurality of partitions to be tested by at least one corresponding clock signal; and
controlling the inter-connections to be tested by at least one corresponding clock signal.
